(19) United States
(12) Patent Application Publication
(10) Pub. No.: US 2024/0141494 A1
(43) Pub. Date: May 2, 2024

(54) SUBSTRATE PROCESSING APPARATUS

(71) Applicant: Tokyo Electron Limited, Tokyo (JP)

(72) Inventor: Kiyoshi MORI, Fuchu City (JP)

(21) Appl. No.: 18/491,848

(22) Filed: Oct. 23, 2023

(30) Foreign Application Priority Data
Oct. 28, 2022 (JP) 2022-173443

(51) Int. Cl. C23C 16/458

(52) U.S. Cl. CPC C23C 16/4584

(57) ABSTRACT

A substrate processing apparatus includes: a processing container; a stage provided inside the processing container to place a substrate; a support member penetrating a through-hole of a bottom portion of the processing container to support the stage from below; a movable member located outside the processing container, connected to an end portion of the support member to move integrally with the stage; a fixed member fixed around the through-hole outside the processing container; and actuators provided in parallel with each other between the fixed member and the movable member to move the movable member and the stage. Each actuator includes a motor and a rod, and expands and contracts the rod by rotation of a rotary shaft of the motor to move the movable member and the stage, and two or more actuators having a predetermined positional relationship are opposite in rotational directions of the rotary shafts of the motors.

### CROSS-REFERENCE TO RELATED APPLICATION

This application is based upon and claims the benefit of priority from Japanese Patent Application No. 2022-173443, filed on Oct. 28, 2022, the entire contents of which are incorporated herein by reference.

### TECHNICAL FIELD

The present disclosure relates to a substrate processing apparatus.

### BACKGROUND

In the related art, there is known a vacuum processing apparatus that includes a processing container which can maintain a vacuum atmosphere therein, a stage provided inside the processing container to place a substrate thereon, a support member extending through a hole of the bottom of the processing container to support the stage from below, a base member engaged with an end portion of the support member located outside the processing container and configured to move integrally with the stage, and a plurality of actuators provided side by side between the bottom of the processing container and the base member and configured to adjust a position and inclination of the stage by moving the base member relative to the bottom of the processing container.

### PRIOR ART DOCUMENT

### Patent Document

Patent Document 1: Japanese Laid-Open Patent Publication No. 2022-014522

### SUMMARY

According to one embodiment of the present disclosure, a substrate processing apparatus includes: a processing container; a stage provided inside the processing container and configured to place a substrate thereon; a support member configured to penetrate a through-hole of a bottom portion of the processing container and support the stage from below; a movable member located outside the processing container, connected to an end portion of the support member, and configured to move integrally with the stage; a fixed member fixed around the through-hole outside the processing container; and a plurality of actuators provided in parallel with each other between the fixed member and the movable member and configured to move the movable member and the stage, wherein each of the plurality of actuators includes a motor and a rod, and is configured to expand and contract the rod by rotation of a rotary shaft of the motor so as to move the movable member and the stage, and wherein two or more actuators having a predetermined positional relationship among the plurality of actuators are opposite in rotational directions of the rotary shafts of the motors.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic plan view showing an example of a configuration of a vacuum processing system according to an embodiment.

FIG. 2 is an exploded perspective view showing an example of a configuration of a vacuum processing apparatus according to the embodiment.

FIG. 3 is a plan view schematically showing an internal configuration of the vacuum processing apparatus according to the embodiment.

FIG. 4 is a schematic cross-sectional view showing an example of the configuration of the vacuum processing apparatus according to the embodiment.

FIG. 5 is a diagram illustrating an example of a configuration of a rotational drive mechanism and an adjustment mechanism according to an embodiment.

FIG. 6 is an explanatory diagram for explaining an example of a rotational direction of a rotary shaft of a motor included in each of a plurality of actuators.

FIG. 7 is an explanatory diagram for explaining an example of control of the motor included in each of the plurality of actuators.

FIG. 8 is a diagram showing another example of arrangement positions of the plurality of motors.

FIG. 9 is an explanatory diagram for explaining another example of the rotational direction of the rotary shaft of the motor included in each of the plurality of actuators.

### DETAILED DESCRIPTION

An embodiment of a substrate processing apparatus disclosed in the subject application will now be described in detail with reference to the drawings. It should be noted that the disclosed substrate processing apparatus is not limited by the following embodiment. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a substrate processing apparatus that adjusts a position of a stage by driving a plurality of actuators, it is common for rotary shafts of motors that drive the plurality of actuators to rotate in the same direction. However, if the rotational directions of the rotary shafts of the motors that drive the actuators are the same, the reaction torques generated by these motors are transmitted to the stage via the base member, which may cause the stage to vibrate. Such vibration of the stage becomes a factor that hinders high-speed movement of the stage. Therefore, a demand has existed for a technique capable of suppressing the vibration of the stage generated when driving a plurality of actuators.

### Embodiment

### [Configuration of Vacuum Processing System]

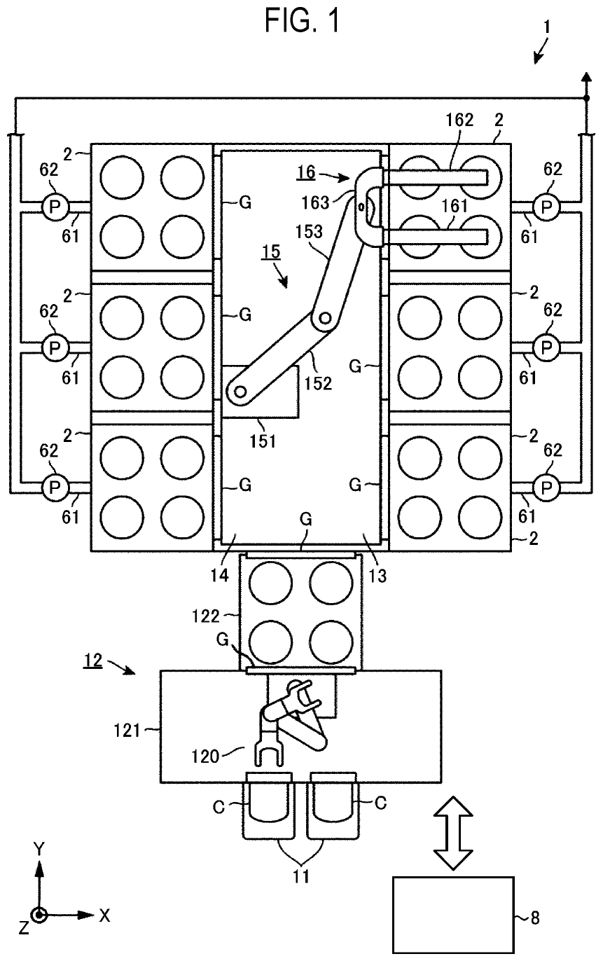

An example of the substrate processing apparatus of the present disclosure will be described. In the following embodiment, a case where the substrate processing apparatus of the present disclosure is applied to a vacuum processing system having a system configuration will be described by way of example. FIG. 1 is a schematic plan view showing an example of a configuration of the vacuum processing system according to an embodiment. The vacuum processing system 1 includes a loading/unloading port 11, a loading/unloading module 12, a vacuum transfer module 13, and a vacuum processing apparatus (an example of a substrate processing apparatus) 2. In FIG. 1, an X direction is a left-right direction, a Y direction is a front-back direction, a Z direction is an up-down direction (height direction), and a position of the loading/unloading port 11 is a front side in the front-back direction. The loading/unloading port 11 is connected to the front side of the loading/unloading module 12, and the vacuum transfer module 13 is connected to the back side of the loading/unloading module 12, so that they face each other in the front-back direction.

A carrier C, which is a transfer container that accommodates substrates to be processed, is placed on the loading/unloading port 11. The substrate is a wafer W which is a circular substrate having a diameter of, for example, 300 mm. The loading/unloading module 12 is a module for loading and unloading the wafer W between the carrier C and the vacuum transfer module 13. The loading/unloading module 12 includes an atmospheric pressure transfer chamber 121 in which the wafer W is delivered to and from the carrier C in an atmospheric-pressure atmosphere by a transfer mechanism 120, and a load lock chamber 122 configured to switch the atmosphere in which the wafer W is placed, between an atmospheric-pressure atmosphere and a vacuum atmosphere.

The vacuum transfer module 13 include a vacuum transfer chamber 14 configured to maintain a vacuum atmosphere therein. A substrate transfer mechanism 15 is arranged inside the vacuum transfer chamber 14. The vacuum transfer chamber 14 is formed, for example, in a rectangular shape having long sides extending along the front-back direction in a plan view. A plurality of (e.g., three) vacuum processing apparatuses 2 are connected to each of the mutually-facing long sides of a rectangle among the four sidewalls of the vacuum transfer chamber 14. Further, a load lock chamber 122 installed in the loading/unloading module 12 is connected to the front short side among the four sidewalls of the vacuum transfer chamber 14. A gate valve G is arranged between the atmospheric pressure transfer chamber 121 and the load lock chamber 122, between the load lock chamber 122 and the vacuum transfer module 13, and between the vacuum transfer module 13 and the vacuum processing apparatus 2. The gate valve G opens and closes a loading/unloading port for the wafer W provided in each of the modules connected to each other.

The substrate transfer mechanism 15 transfers the wafer W between the loading/unloading module 12 and the vacuum processing apparatus 2 in a vacuum atmosphere. The substrate transfer mechanism 15 is constituted with a multi jointed arm and includes a substrate holding part 16 that holds the wafer W. The vacuum processing apparatus 2 performs substrate processing on a plurality of wafers W (e.g., four wafers) at the same time using a processing gas in a vacuum atmosphere. Therefore, the substrate holding part 16 of the substrate transfer mechanism 15 is configured to be able to hold, for example, four wafers W so as to deliver the four wafers W to the vacuum processing apparatus 2 at the same time.

Specifically, the substrate transfer mechanism 15 includes, for example, a base 151, a horizontally-extending first arm 152, a horizontally-extending second arm 153, and a substrate holding part 16. A proximal side of the first arm 152 is provided on the base 151 so as to swivel about a vertical swivel axis on the base 151. A proximal side of the second arm 153 is provided on a distal end portion of the first arm 152 so as to swivel about a vertical swivel axis on the distal end portion of the first arm 152. The substrate holding part 16 includes a first substrate holding portion 161, a second substrate holding portion 162, and a connecting portion 163. The first substrate holding portion 161 and the second substrate holding portion 162 are configured to have a shape of two elongated spatulas that extend horizontally in parallel with each other. The connecting portion 163 extends horizontally so as to be perpendicular to an extension direction of the first and second substrate holding portions 161 and 162, and connects the proximal ends of the first and second substrate holding portions 161 and 162 to each other. A longitudinally central portion of the connecting portion 163 is provided on the distal end portion of the second arm 153 so as to swivel about a vertical swivel axis on the distal end portion of the second arm 153. The first substrate holding portion 161 and the second substrate holding portion 162 will be described later.

The vacuum processing system 1 includes a controller 8. The controller 8 is, for example, a computer including a processor, a memory, an input device, a display device, and the like. The controller 8 controls each part of the vacuum processing system 1. The controller 8 enables an operator to use the input device to perform command input operations and the like to manage the vacuum processing system 1. In addition, in the controller 8, the operation status of the vacuum processing system 1 can be visualized and displayed using the display device. Further, the memory of the controller 8 stores a control program for controlling various processes executed in the vacuum processing system 1 using the processor, recipe data, and the like. Desired substrate processing is performed in the vacuum processing system 1 by the processor of the controller 8 executing the control program and controlling each part of the vacuum processing system 1 according to the recipe data.

### [Configuration of Vacuum Processing Apparatus]

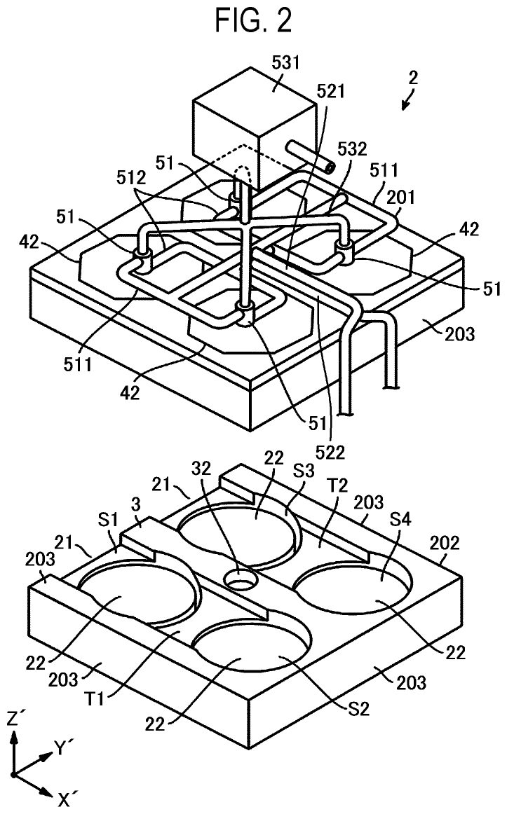

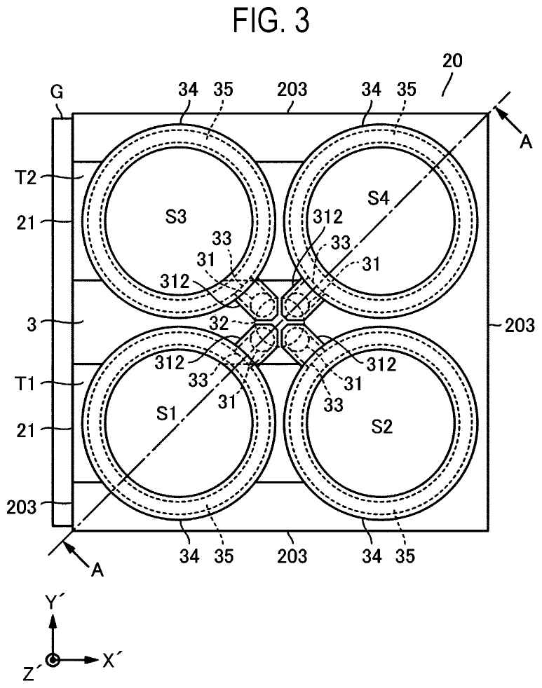

Next, the vacuum processing apparatus 2 will be described with reference to FIGS. 2 to 4. An example in which the vacuum processing apparatus 2 is applied to, for example, a film forming apparatus that performs plasma CVD (Chemical Vapor Deposition) processing on a wafer W, will be described below. FIG. 2 is an exploded perspective view showing an example of a configuration of the vacuum processing apparatus 2 according to the embodiment. FIG. 3 is a plan view schematically showing an internal configuration of the vacuum processing apparatus 2 according to the embodiment.

Six vacuum processing apparatuses 2 are configured in the same way. The six vacuum processing apparatuses 2 may process the wafers W in a parallel manner. The vacuum processing apparatus 2 includes a processing container (vacuum container) 20 having a rectangular shape in a plan view. The processing container 20 is configured to be able to maintain a vacuum atmosphere therein. The processing container 20 is constructed by closing a concave opening on an upper surface of a container main body 202 with a ceiling member 201. The processing container 20 has, for example, a sidewall portion 203 surrounding a periphery the processing container 20. Among the four sidewall portions 203, two loading/unloading ports 21 are formed in the sidewall portion 203 connected to the vacuum transfer chamber 14 so as to be arranged side by side in the front-back direction (Y′ direction in FIG. 2). The loading/unloading port 21 is opened and closed by a gate valve G.

As shown in FIGS. 2 and 3, inside the processing container 20, a first transfer space T1 and a second transfer space T2, which extend horizontally from each loading/unloading port 21 so that the wafer W is transferred therein, are located adjacent to each other. Further, an intermediate wall portion 3 is provided between the first transfer space T1 and the second transfer space T2 in the processing container 20 along the extension direction (X′ direction in FIG. 2). Two processing spaces S1 and S2 are arranged along the extension direction in the first transfer space T1, and two processing spaces S3 and S4 are arranged along the extension direction in the second transfer space T2. Therefore, in the processing container 20, a total of four processing spaces S1 to S4 are arranged in a 2×2 matrix when viewed from above. The term “horizontal direction” as used herein includes a case where the wafer W is slightly tilted in the extension direction, to the extent there is no influence such as contact between devices during the loading/unloading operation of the wafer W or the like in the influence of a manufacturing tolerance or the like.

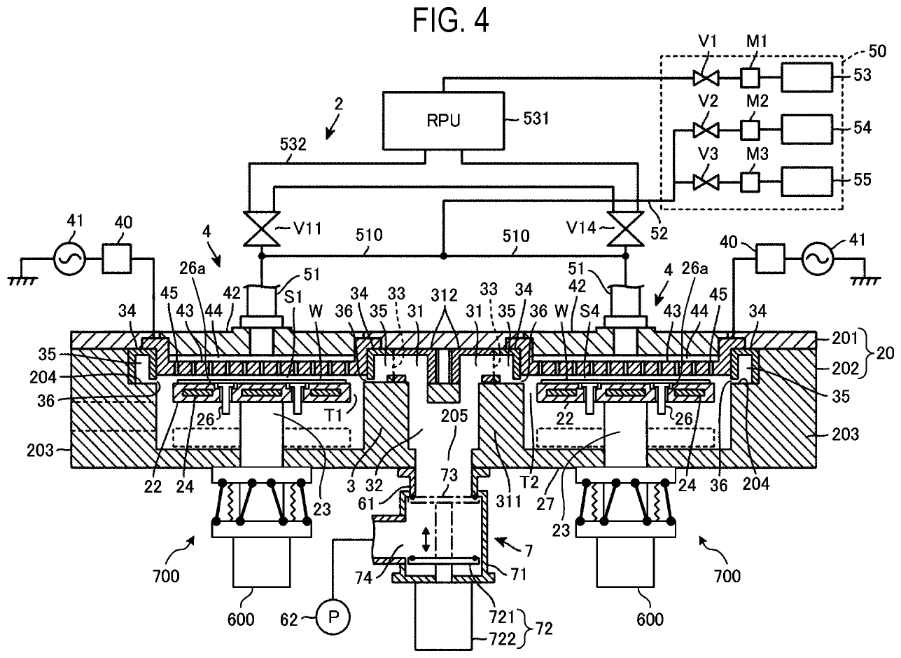

FIG. 4 is a schematic cross-sectional view showing an example of a configuration of the vacuum processing apparatus 2 according to the embodiment. The cross section of FIG. 4 corresponds to a cross section of the vacuum processing apparatus 2 taken along the line A-A in FIG. 3. The four processing spaces S1 to S4 are configured similarly to each other. Each of the four processing spaces S1 to S4 is formed between the stage 22 on which the wafer W is placed and the gas supplier 4 disposed to face the stage 22. In other words, in the processing container 20, the stage 22 and the gas supplier 4 are provided for each of the four processing spaces S1 to S4. FIG. 4 shows the processing space S1 of the first transfer space T1 and the processing space S4 of the second transfer space T2. The processing space S1 will be described below by way of example.

The stage 22 also serves as a lower electrode, and is formed in a flat cylindrical shape made of, for example, metal or aluminum nitride (AlN) with a metal or a metal mesh electrode embedded therein. The stage 22 is supported from below by the support member 23. The support member 23 is formed in a cylindrical shape, extends vertically downward, and penetrates the bottom portion 27 of the processing container 20. A lower end portion of the support member 23 is located outside the processing container 20 and is connected to the rotational drive mechanism 600. The support member 23 is rotated by the rotational drive mechanism 600. The stage 22 is configured to be rotatable with the rotation of the support member 23. Further, an adjustment mechanism 700 for adjusting a position and inclination of the stage 22 is provided at the lower end portion of the support member 23. The stage 22 is configured to move up and down between a processing position and a delivery position via the support member 23 by the adjustment mechanism 700. In FIG. 4, the stage 22 located at the processing position is depicted by a solid line, and the stage 22 located at the delivery position is depicted by a broken line. The processing position is a position where substrate processing (e.g., film formation processing) is performed, and the delivery position is a position where the wafer W is delivered to and from the substrate transfer mechanism 15. The rotational drive mechanism 600 and the adjustment mechanism 700 will be described later.

A heater 24 is embedded in the stage 22. The heater 24 heats each wafer W placed on the stage 22 to about 60 degrees C. to 600 degrees C., for example. In addition, the stage 22 is connected to a ground potential.

Further, the stage 22 is provided with a plurality (e.g., three) of pin through-holes 26a. Lift pins 26 are arranged inside the pin through-holes 26a, respectively. The pin through-holes 26a are provided so as to penetrate the stage 22 from the placement surface (upper surface) of the stage 22 to the back surface (lower surface) opposite to the placement surface. The lift pins 26 are slidably inserted into the pin through-holes 26a, respectively. Upper ends of the lift pins 26 are suspended from the side of the placement surface of the pin through-holes 26a. That is, the upper ends of the lift pins 26 have a larger diameter than the pin through-holes 26a. In the upper ends of the pin through-holes 26a, recesses having a larger diameter and thickness than the upper ends of the lift pins 26 and capable of accommodating the upper ends of the lift pins 26 are formed. As a result, the upper ends of the lift pins 26 are locked to the stage 22 and suspended from the side of the placement surface of the pin through-holes 26a. Further, lower ends of the lift pins 26 protrude from the back surface of the stage 22 toward the bottom portion 27 of the processing container 20.

As shown in FIG. 4, when the stage 22 is raised to the processing position, the upper ends of the lift pins 26 are accommodated in the recesses on the side of the placement surface of the pin through-holes 26a. When the stage 22 is lowered from this state to the delivery position, the lower ends of the lift pins 26 come into contact with the bottom portion 27 of the processing container 20, and the lift pins 26 are moved into the pin through-holes 26a so that the upper ends of the lift pins 26 protrude from the placement surface of the stage 22. The processing container 20 may be provided with a lift-pin contact member on the bottom side thereof, and may be configured such that the lower ends of the lift pins 26 are brought into contact with the lift-pin contact member. The lift pins 26 may be moved up and down by the upward and downward movement of the lift-pin contact member.

The first and second substrate holding portions 161 and 162 will now be described. The first substrate holding portion 161 is configured to, when entering the first transfer space T1, hold the wafer W at positions corresponding to the arrangement positions of the processing spaces S1 and S2 in the first transfer space T1. The positions corresponding to the arrangement positions of the processing spaces S1 and S2 in the first transfer space T1 are positions set so that the wafers W can be delivered to the two stages 22 provided in the processing spaces S1 and S2 of the first transfer space T1. Further, the second substrate holding portion 162 is configured to, when entering the second transfer space T2, hold the wafer W at positions corresponding to the arrangement positions of the processing spaces S3 and S4 in the second transfer space T2. The positions corresponding to the arrangement positions of the processing spaces S3 and S4 in the first transfer space T1 are positions set so that the wafers W can be delivered to the two stages 22 provided in the processing spaces S3 and S4 of the second transfer space T2.

For example, a width of each of the first and second substrate holding portions 161 and 162 is smaller than the diameter of the wafer W. The back surface of the wafer W is supported on each of the first and second substrate holding portions 161 and 162 at a distance from the distal end side and the proximal end side. For example, the wafers W supported on the distal end side of the first and second substrate holding portions 161 and 162 have central portions supported by the distal ends of the first and second substrate holding portions 161 and 162.

In this manner, the cooperative action of the substrate transfer mechanism 15, the lift pins 26, and the stage 22 allows, for example, four wafers W to be delivered between the substrate transfer mechanism 15 and the respective stages 22 at the same time.

The gas supplier 4 is provided above the stage 22 on the ceiling member 201 of the processing container 20 via a guide member 34 made of an insulating material. The gas supplier 4 has a function as an upper electrode. The gas supplier 4 includes a lid 42, a shower plate 43 having a surface provided to face the placement surface of the stage 22, and a gas flow chamber 44 formed between the lid 42 and the shower plate 43. A gas supply pipe 51 is connected to the lid 42. Gas discharge holes 45 penetrating the shower plate 43 in the thickness direction are formed in, for example, a vertically and horizontally arranged state. The shower plate 43 discharges a gas from each gas discharge hole 45 toward the stage 22 in the form of a shower.

Each gas supplier 4 is connected to a gas supply system 50 via a gas supply pipe 51. The gas supply system 50 includes, for example, sources of a reaction gas (film-forming gas) as a processing gas, a purge gas, and a cleaning gas, pipes, valves V, flow rate adjusters M, and the like.

A radio-frequency power source 41 is connected to the shower plate 43 via a matching device 40. The shower plate 43 functions as an upper electrode that faces the stage 22. When radio-frequency power is applied between the shower plate 43, which is the upper electrode, and the stage 22, which is the lower electrode, the gas (in this example, the reaction gas) supplied from the shower plate 43 to the processing space S1 may be plasmarized by capacitive coupling.

Next, exhaust passages and a junction exhaust passage formed in the intermediate wall portion 3 will be described. As shown in FIGS. 3 and 4, the intermediate wall portion 3 is formed with exhaust passages 31 provided for the four processing spaces S1 to S4, and a junction exhaust passage 32 where these exhaust passages 31 are joined with each other. The junction exhaust passage 32 extends in the vertical direction within the intermediate wall portion 3. The intermediate wall portion 3 includes a wall portion main body 311 provided on the side of the container main body 202, and an exhaust passage forming member 312 provided on the side of the ceiling member 201. The exhaust passages 31 are provided inside the exhaust passage forming member 312.

Further, an exhaust port 33 is formed for each of the processing spaces S1 to S4 on the wall surface of the intermediate wall portion 3 positioned on the outer side of the processing spaces S1 to S4. Each exhaust passage 31 is formed in the intermediate wall portion 3 so as to connect the exhaust port 33 and the junction exhaust passage 32. For example, each exhaust passage 31 extends horizontally in the intermediate wall portion 3. Then, each exhaust passage 31 bends downward and extends vertically. Each exhaust passage 31 is connected to the junction exhaust passage 32. For example, each exhaust passage 31 has a circular cross section (see FIG. 3). The downstream end of each exhaust passage 31 is connected to an upstream end of the junction exhaust passage 32, and an upstream side of each exhaust passage 31 is opened as the exhaust port 33 to the outside of each of the processing space S1 to S4.

A guide member 34 for exhaust is provided around each of the processing spaces S1 to S4 so as to surround each of the processing spaces S1 to S4. The guide member 34 is, for example, an annular body provided so as to surround a region around the stage 22 in the processing position in a spaced-apart relationship with the stage 22. The guide member 34 is configured to form therein an annular flow passage 35 having, for example, a rectangular longitudinal cross section and an annular shape in a plan view. FIG. 3 schematically shows the processing spaces S1 to S4, the guide member 34, the exhaust passages 31, and the junction exhaust passage 32.

As shown in FIG. 4, the guide member 34 has, for example, a U-shaped vertical cross section, and is arranged so that an opening of the U-shaped portion faces downward. The guide member 34 is fitted in a recess 204 formed on the side of the intermediate wall portion 3 and the sidewall portion 203 of the container main body 202. The guide member 34 forms a flow path 35 between itself and a member constituting the intermediate wall portion 3 and the sidewall portion 203.

The guide member 34 fitted into the recess 204 forms a slit-shaped slit exhaust port 36 opened toward the processing spaces S1 to S4. In this way, the slit exhaust ports 36 are formed along a circumferential direction at the side peripheries of the processing spaces S1 to S4. The exhaust port 33 is connected to the flow path 35 to allow the processing gas exhausted from the slit exhaust port 36 to flow toward the exhaust port 33.

A set of two processing spaces S1 and S2 arranged along the extension direction of the first transfer space T1, and a set of two processing spaces S3 and S4 arranged along the extension direction of the second transfer space T2 are focused. As shown in FIG. 3, the set of processing spaces S1 and S2 and the set of processing spaces S3 and S4 are arranged 180 degrees rotationally symmetrically around the junction exhaust passage 32 when viewed from above.

Thus, the processing gas flow path extending from each of the processing spaces S1 to S4 to the junction exhaust passage 32 via the slit exhaust port 36, the flow path 35 of the guide member 34, the exhaust port 33, and the exhaust passage 31 is formed 180 degrees rotationally symmetrically around the junction exhaust passage 32. If the positional relationship with the first and second transfer spaces T1 and T2 and the intermediate wall portion 3 is disregarded and only the processing gas flow paths are focused, it can be said that the flow paths are formed 90 degrees rotationally symmetrically around the junction exhaust passage 32 when viewed from above.

The junction exhaust passage 32 is connected to the exhaust pipe 61 via a junction exhaust port 205 formed in the bottom portion 27 of the processing container 20. The exhaust pipe 61 is connected via the valve mechanism 7 to a vacuum pump 62 that constitutes an evacuation mechanism. For example, one vacuum pump 62 is provided in one processing container 20 (see FIG. 1). The exhaust pipes 61 on the downstream side of the respective vacuum pumps 62 are joined together and connected to, for example, a factory exhaust system.

The valve mechanism 7 opens and closes the processing gas flow path formed in the exhaust pipe 61. The valve mechanism 7 includes, for example, a casing 71 and an opening/closing part 72. A first opening 73 is formed on an upper surface of the casing 71 and is connected to the exhaust pipe 61 on the upstream side thereof. A second opening 74 is formed on the side surface of the casing 71 and is connected to the exhaust pipe 61 on the downstream side thereof.

The opening/closing part 72 includes, for example, an opening/closing valve 721 formed in such a size that closes the first opening 73, and a lifting mechanism 722 provided outside the casing 71 and configured to raise and lower the opening/closing valve 721 inside the casing 71. The opening/closing valve 721 is configured to move up and down between a closed position in which the opening/closing valve 721 closes the first opening 73 as indicated by a one-dot chain line in FIG. 4, and an open position in which the opening/closing valve 721 retreats to below the first and second openings 73 and 74 as indicated by a solid line in FIG. 4. When the opening/closing valve 721 is at the closed position, the downstream end of the junction exhaust port 205 is closed and the evacuation inside the processing container 20 is stopped. Further, when the opening/closing valve 721 is at the open position, the downstream end of the junction exhaust port 205 is opened and the interior of the processing container 20 is evacuated.

Next, a process gas supply system will be described with reference to FIG. 2 by taking as an example a case where two kinds of reaction gases are used. The gas supply pipe 51 is connected to approximately the center of the upper surface of each gas supplier 4. The gas supply pipe 51 is connected to a first reaction gas source 541 and a purge gas source 55 via a first common gas supply passage 521 by a first gas supply pipe 511. The gas supply pipe 51 is also connected to a second reaction gas source 542 and the purge gas source 55 via a second common gas supply passage 522 by a second gas supply pipe 512. In FIG. 4, for the sake of convenience in description, the first common gas supply passage 521 and the second common gas supply passage 522 are collectively shown as a gas supply passage 52. Further, the first reaction gas source 541 and the second reaction gas source 542 are collectively shown as a reaction gas source 54. Further, the first gas supply pipe 511 and the second gas supply pipe 512 are shown collectively as a gas supply pipe 510. A valve V2 and a flow rate adjuster M2 are used for supplying a reaction gas, and a valve V3 and a flow rate adjuster M3 are used for supplying a purge gas.

Further, the gas supply pipe 51 is connected to a cleaning gas source 53 via a remote plasma unit (RPU) 531 by a cleaning gas supply passage 532. The cleaning gas supply passage 532 is branched into four systems on the downstream side of the RPU 531 and is connected to the gas supply pipe 51. A valve V1 and a flow rate adjuster M1 are provided on the upstream side of the RPU 531 in the cleaning gas supply passage 532. Further, valves V11 to V14 are provided for the respective branched pipes on the downstream side of the RPU 531. During cleaning, the corresponding valves V11 to V14 are opened. In FIG. 4, for the sake of convenience in description, only the valves V11 and V14 are shown. The gas supply system 50 supplies various gases used for film formation. If a case of forming an insulating oxide film (SiO₂) by CVD is taken as an example, the reaction gas may be, for example, a tetraethoxysilane (TEOS) gas or an oxygen (O₂) gas, and the purge gas may be, for example, an inert gas such as a nitrogen (N₂) gas or the like. When using the TEOS gas and the O₂ gas as the reaction gas, for example, the TEOS gas is supplied from the first reaction gas source 541, and the O₂ gas is supplied from the second reaction gas source 542. For example, a nitrogen trifluoride (NF₃) gas is used as the cleaning gas.

When viewed from the processing gas distributed from the common gas supply passage 52, the respective processing gas paths from the respective gas supply pipes 51 to the gas suppliers 4 are formed so as to have the same conductance. For example, as shown in FIG. 2, the downstream side of the first common gas supply passage 521 is branched into two systems, and the branched gas supply passages are further branched into two systems so that the first gas supply pipes 511 are formed in a tournament shape. The first gas supply pipes 511 are connected to the respective gas supply pipes 51 on the downstream side of the cleaning gas valves V11 to V14. Further, the downstream side of the second common gas supply passage 522 is branched into two systems, and the branched gas supply passages are further branched into two systems so that the second gas supply pipes 512 are formed in a tournament shape. The second gas supply pipes 512 are connected to the gas supply pipes 51 on the downstream side of the cleaning gas valves V11 to V14.

The respective first gas supply pipes 511 are formed such that the length and inner diameter from an upstream end (an end connected to the first common gas supply passage 521) to a downstream end (an end connected to the gas supplier 4 or the gas supply pipe 51) are the same between the first gas supply pipes 511. Further, the respective second gas supply pipes 512 are formed such that the length and inner diameter from an upstream end (an end connected to the second common gas supply passage 522) to a downstream end are the same between the second gas supply pipes 512. In this way, when viewed from the processing gas distributed from the first common gas supply passage 521, the respective processing gas paths leading to the junction exhaust passage 32 through the first gas supply pipes 511, the gas suppliers 4, the processing spaces S1 to S4, and the exhaust passages 31 are formed so as to have the same conductance. In addition, when viewed from the processing gas distributed from the second common gas supply passage 522, the respective processing gas paths leading to the junction exhaust passage 32 through the second gas supply pipes 512, the gas suppliers 4, the processing spaces S1 to S4, and the exhaust passages 31 are formed so as to have the same conductance.

The vacuum processing apparatus 2 is connected to the controller 8 of the vacuum processing system 1. The controller 8 controls each part of the vacuum processing apparatus 2. The controller 8 enables an operator to use an input device to perform command input operations and the like to manage the vacuum processing apparatus 2. Further, in the controller 8, the operating status of the vacuum processing apparatus 2 can be visualized and displayed using a display device. Further, the memory of the controller 8 stores a control program for controlling various processes executed in the vacuum processing apparatus 2 by the processor, and recipe data. A desired process is executed in the vacuum processing apparatus 2 by the processor of the controller 8 executing the control program and controlling each part of the vacuum processing apparatus 2 according to the recipe data. For example, the controller 8 controls each part of the vacuum processing apparatus 2 to perform substrate processing such as etching and film formation on a substrate loaded into the vacuum processing apparatus 2.

### [Configuration of Rotational Drive Mechanism and Adjustment Mechanism]

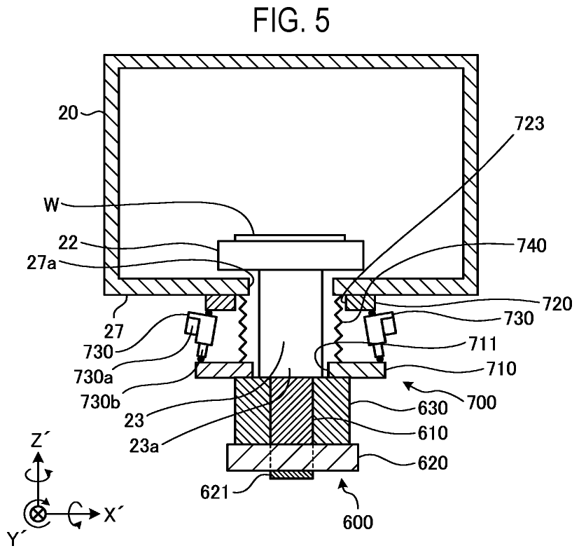

FIG. 5 is a diagram showing an example of a configuration of the rotational drive mechanism 600 and the adjustment mechanism 700 according to the embodiment. A through-hole 27a is formed in the bottom portion 27 of the processing container 20 at a position corresponding to the position where the stage 22 is supported. The support member 23 that supports the stage 22 from below is inserted into the through-hole 27a. A rotational drive mechanism 600 is connected to the lower end portion 23a of the support member 23 located outside the processing container 20.

The rotational drive mechanism 600 includes a rotary shaft 610, a motor 620 and a vacuum seal 630.

The rotary shaft 610 is connected to the lower end portion 23a of the support member 23, and is configured to be rotatable integrally with the support member 23. A slip ring 621 is provided at the lower end portion of the rotary shaft 610. The slip ring 621 has electrodes and is electrically connected to various wirings for supplying electric power to the parts around the stage 22. For example, the slip ring 621 is electrically connected to a wiring for supplying electric power to the heater 24 embedded in the stage 22. In addition, for example, when an electrostatic chuck for electrostatically attracting the wafer W is provided on the stage 22, the slip ring 621 is electrically connected to a wiring for a DC voltage applied to the electrostatic chuck.

The motor 620 is connected to the rotary shaft 610 to rotate the rotary shaft 610. When the rotary shaft 610 rotates, the stage 22 is rotated via the support member 23. As the rotary shaft 610 rotates, the slip ring 621 also rotates together with the rotary shaft 610 to maintain the electrical connection between the slip ring 621 and various wirings for supplying electric power to the parts around the stage 22.

A vacuum seal 630 is, for example, a magnetic fluid seal. The vacuum seal 630 is provided around the rotary shaft 610, and is configured to maintain the rotation of the rotary shaft 610 while airtightly sealing the rotary shaft 610.

Further, an adjustment mechanism 700 is connected to the lower end portion 23a of the support member 23 via a vacuum seal 630.

The adjustment mechanism 700 includes a movable member 710, a fixed member 720, a plurality of (e.g., six) actuators 730, and a bellows 740.

The movable member 710 is, for example, a disc-shaped member, and is located outside the processing container 20. The movable member 710 is configured to move integrally with the stage 22 because the lower end portion 23a of the support member 23 located outside the processing container 20 is connected to the movable member 710 via the vacuum seal 630. For example, a hole 711 having a larger diameter than the lower end portion 23a of the support member 23 is formed in the movable member 710. The support member 23 passes through the hole 711, and the lower end portion 23a of the support member 23 is connected to the rotary shaft 610. The vacuum seal 630 is provided around the rotary shaft 610 connected to the lower end portion 23a of the support member 23, and the movable member 710 is fixed to the upper surface of the vacuum seal 630. Thus, the movable member 710 is connected to the stage 22 via the vacuum seal 630, the rotary shaft 610, the support member 23 and the like, and can move integrally with the stage 22.

The fixed member 720 is, for example, a disc-shaped member, and is fixed around the through-hole 27a on the outside of the processing container 20. A hole 723 communicating with the through-hole 27a of the bottom portion 27 of the processing container 20 is formed in the fixed member 720.

The plurality of actuators 730 are provided in parallel with each other between the fixed member 720 and the movable member 710. The actuators 730 are configured to move the stage 22 together with the movable member 710 relative to the bottom portion 27 of the processing container 20. The actuators 730 may adjust the position and inclination of the stage 22 by moving the movable member 710 relative to the bottom portion 27 of the processing container 20. Each of the actuators 730 has one end portion rotatably and slidably connected to the fixed member 720 via a universal joint, and the other end (the distal end portion of a rod 730b to be described later) rotatably and slidably connected to the movable member 710 via a spherical bearing.

Each of the actuators 730 includes a motor 730a, a ball screw (not shown), and an extendable rod 730b. The motor 730a is, for example, a servo motor having a rotatable rotary shaft. The ball screw is provided inside each of the actuators 730, and is configured to be rotatable in the same direction as the rotational direction (hereinafter referred to as “rotational direction R”) of the rotary shaft of the motor 730a together with the rotation of the motor 730a. The rod 730b is connected at its distal end portion to the movable member 710 via a spherical bearing. Each of the actuators 730 moves the movable member 710 and the stage 22 relative to the fixed member 720 by expanding and contracting the rod 730b via the ball screw through the rotation of the rotary shaft of the motor 730a. Thus, the actuators 730 can adjust the position and inclination of the stage 22. The actuators 730 and the movable member 710 constitute a parallel link mechanism capable of moving the movable member 710, for example, in the directions of the X′, Y′, and Z′ axes and in the rotational directions about the X′, Y′, and Z′ axes as shown in FIG. 5. The movement coordinate system of the parallel link mechanism constituted by the actuators 730 and the movable member 710 is adjusted in advance to match the coordinate system of the processing container 20. By connecting the bottom portion 27 of the processing container and the movable member 710 by the parallel link mechanism, it is possible for the actuators 730 to move the movable member 710 relative to the bottom portion 27 of the processing container 20. This makes it possible to adjust the position and inclination of the stage 22. For example, the actuators 730 adjust the position of the stage 22 by moving the movable member 710 in a direction perpendicular to the outer wall surface of the bottom portion 27 of the processing container 20 (for example, the Z′ axis direction in FIG. 5). In addition, for example, the actuators 730 adjust the position of the stage 22 by moving the movable member 710 in the directions along the outer wall surface of the bottom portion 27 of the processing container 20 (e.g., the X′-axis direction and the Y′-axis direction in FIG. 5). Further, for example, the actuators 730 adjust the inclination of the stage 22 by tilting the movable member 710 in a predetermined direction (e.g., the rotational direction about the X′ axis and the rotational direction about the Y′ axis in FIG. 5) with respect to the outer wall surface of the bottom portion 27 of the processing container 20.

The position and inclination of the stage 22 adjusted by the actuators 730 may be identified by detecting the position and inclination of the movable member 710 using various detection means. Examples of the detection means include a linear encoder, a gyro sensor, a three-axis acceleration sensor, a laser tracker, and the like.

The bellows 740 is provided so as to surround the support member 23. The bellows 740 has an upper end connected to the bottom portion 27 of the processing container 20 through the hole 723 formed in the fixed member 720, and a lower end connected to the movable member 710. Thus, the bellows 740 hermetically seals the space between the bottom portion 27 of the processing container 20 and the movable member 710. The bellows 740 is configured to be expandable and retractable in response to the movement of the movable member 710.

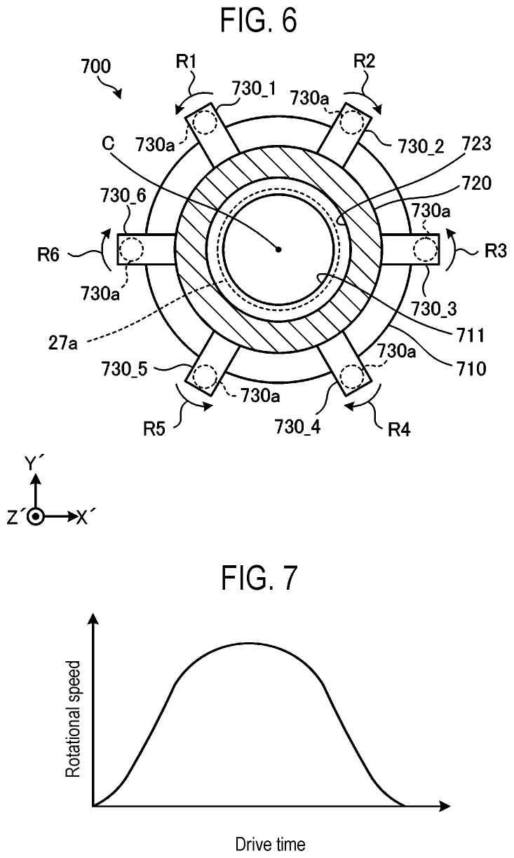

FIG. 6 is an explanatory diagram for explaining an example of the rotational direction R of the rotary shaft of the motor 730a included in the actuators 730. FIG. 6 shows a top view of the adjustment mechanism 700 viewed from above (in the positive direction of the Z′-axis). Further, in FIG. 6, for the sake of convenience of explanation, the fixed member 720 of the adjustment mechanism 700 is hatched. Further, in FIG. 6, the through-hole 27a of the bottom portion 27 of the processing container 20 is indicated by a broken line.

As shown in FIG. 6, in the adjustment mechanism 700 of the vacuum processing apparatus 2 according to the embodiment, two or more actuators 730 having a predetermined positional relationship among the plurality of (six, in FIG. 6) actuators 730 are opposite in the rotational directions R of the rotary shafts of the motors 730a.

For example, among the plurality of actuators 730_1 to 730_6 shown in FIG. 6, the rotational directions R1 and R4 of the motors 730a of the two actuators 730_1 and 730_4 facing each other across the center C of the through-hole 27a are opposite to each other. Among the plurality of actuators 730_1 to 730_6, the rotational directions R2 and R5 of the motors 730a of the two actuators 730_2 and 730_5 facing each other across the center C of the through-hole 27a are opposite to each other. Among the plurality of actuators 730_1 to 730_6, the rotational directions R3 and R6 of the motors 730a of the two actuators 730_3 and 730_6 facing each other across the center C of the through-hole 27a are opposite to each other. That is, among the plurality of actuators 730 shown in FIG. 6, the rotational directions R of the motors 730a of two or more actuators 730 facing each other across the center C of the through-hole 27a are opposite to each other.

In the vacuum processing apparatus 2 in which the position of the stage 22 is adjusted by driving the actuators 730, it is general that the rotational directions R of the rotary shafts of the motors 730a that drive the actuators 730 are the same. However, when the rotational directions R of the rotary shafts of the motors 730a that drive the actuators 730 are the same, the reaction torques generated in these motors 730a may be transmitted to the stage 22 via the movable member 710, thereby causing the stage 22 to vibrate. Such vibration of the stage 22 becomes a factor that prevents the stage 22 from moving at a high speed.

On the other hand, in the vacuum processing apparatus 2 according to the embodiment, the rotational directions R of the rotary shafts of the motors 730a of two or more actuators 730 facing each other across the center C of the through-hole 27a are opposite directions. Therefore, the reaction torques generated in these motors 730a cancel each other. Thus, the reaction torques transmitted from the motors 730a of the actuators 730 to the stage 22 are reduced. As a result, according to the vacuum processing apparatus 2 of the embodiment, it is possible to suppress vibration of the stage 22 due to the driving of the actuators 730.

Further, in the vacuum processing apparatus 2 according to the embodiment, in all the actuators 730 of the vacuum processing apparatus 2, the rotational directions R of the rotary shafts of the motors 730a of the actuators 730 facing each other across the center C of the through-hole 27a may be opposite to each other.

With this configuration, it is possible to most effectively cancel the reaction torques in the motors 730a of the actuators 730. Therefore, according to the vacuum processing apparatus 2 having such a configuration, it is possible to further suppress the vibration of the stage 22 due to the driving of the actuators 730.

Further, in the vacuum processing apparatus 2 according to the embodiment, the rotational directions R of the rotary shafts of the motors 730a of two or more actuators 730 adjacent to each other along the circumferential direction of the through-hole 27a among the plurality of actuators 730 may be opposite to each other.

For example, among the plurality of actuators 730 shown in FIG. 6, the rotational directions R1 and R2 of the motors 730a of two actuators 730_1 and 730_2 adjacent to each other along the circumferential direction of the through-hole 27a are opposite to each other. Further, among the plurality of actuators 730, the rotational directions R3 and R4 of the motors 730a of two actuators 730_3 and 730_4 adjacent to each other along the circumferential direction of the through-hole 27a are opposite to each other. Further, among the plurality of actuators 730, the rotational directions R5 and R6 of the motors 730a of two actuators 730_5 and 730_6 adjacent to each other along the circumferential direction of the through-hole 27a are opposite to each other. That is, among the plurality of actuators 730 shown in FIG. 6, the rotational directions R of the motors 730a of two or more actuators 730 adjacent to each other along the circumferential direction of the through-hole 27a are opposite to each other.

As described above, in the vacuum processing apparatus 2 according to the embodiment, the rotational directions R of the rotary shafts of the motors 730a of two or more actuators 730 adjacent along the circumferential direction of the through-hole 27a may be opposite to each other. With such a configuration, the reaction torques of the motors 730a cancel each other. Therefore, it is possible to suppress the vibration of the stage 22 due to the driving of the actuators 730.

Further, with the vacuum processing apparatus 2 according to the embodiment, in all the actuators 730 of the vacuum processing apparatus 2, the rotational directions R of the rotary shafts of the motors 730a of the actuators 730 adjacent to each other along the circumferential direction of the through-hole 27a may be opposite to each other.

With this configuration, it is possible to most effectively cancel the reaction torques generated in the motors 730a of the actuators 730. Therefore, according to the vacuum processing apparatus 2 having such a configuration, it is possible to further suppress the vibration of the stage 22 due to the driving of the actuators 730.

Returning to FIG. 5, the motors 730a of the plurality of actuators 730 are arranged at positions closer to the bottom portion 27 of the processing container 20 than the movable member 710. By arranging the motors 730a closer to the bottom portion 27 of the processing container 20 than the movable member 710, the reaction torques generated in the motors 730a are less likely to be transmitted to the stage 22 via the movable member 710. Therefore, according to the vacuum processing apparatus 2 of the embodiment, it is possible to further suppress the vibration of the stage 22 due to the driving of the actuators 730.

In a case where the motors 730a are located close to the bottom portion 27 of the processing container 20, there is a possibility that the motors 730a may malfunction as the heat of the substrate processing performed in the processing container 20 is transmitted to the motors 730a via the bottom portion 27. On the other hand, in the vacuum processing apparatus 2, at least one of the bottom portion 27 of the processing container 20 and the fixed member 720 may be provided with a temperature control mechanism such as a flow path through which a temperature control fluid such as a refrigerant or the like flows. With this configuration, it is possible to reduce the risk of failure of the motor 730a due to the heat of substrate processing performed in the processing container 20.

FIG. 7 is an explanatory diagram for explaining an example of control of the motors 730a of the actuators 730. In FIG. 7, a time-dependent change in the rotation speed of the rotary shaft of the motor 730a is shown.

As shown in FIG. 7, in the vacuum processing apparatus 2, the rotation speed of the rotary shaft of the motor 730a may be controlled according to a cam curve. The cam curve referred to herein may be, for example, a function representing the rotation speed of the rotary shaft of the motor 730a and the drive time of the motor 730a by a curve. By controlling the rotation speed of the rotary shaft of the motor 730a according to the cam curve, the rod 730b expands and contracts smoothly without abrupt changes in each of the actuators 730. Therefore, according to the vacuum processing apparatus 2 of the embodiment, it is possible to further suppress the vibration of the stage 22 due to the driving of the actuators 730.

### Effects

As described above, the substrate processing apparatus (e.g., the vacuum processing apparatus 2) according to the embodiment includes a processing container (e.g., the processing container 20), a stage (e.g., the stage 22), and a support member (e.g., the support member 23). The substrate processing apparatus also includes a movable member (e.g., the movable member 710), a fixed member (e.g., the fixed member 720), and a plurality of actuators (e.g., the actuators 730). The stage is provided inside the processing container, and a substrate (e.g., the wafer W) is placed on the stage. The support member passes through a through-hole (e.g., the through-hole 27a) of a bottom portion (e.g., the bottom portion 27) of the processing container and supports the stage from below. The movable member is located outside the processing container, and is connected to an end portion (e.g., the lower end portion 23a) of the support member so as to be movable integrally with the stage. The fixed member is fixed around the through-hole outside the processing container. The actuators are provided in parallel with each other between the fixed member and the movable member, and are configured to move the movable member and the stage. Each of the actuators includes a motor (e.g., the motor 730a) and a rod (e.g., the rod 730b), and moves the movable member and the stage by expanding and contracting the rod by the rotation of the rotary shaft of the motor. Two or more actuators having a predetermined positional relationship among the plurality of actuators are opposite in rotational directions (e.g., the rotational directions R) of the rotary shafts of the motors. Therefore, according to the substrate processing apparatus of the embodiment, it is possible to suppress the vibration of the stage due to the driving of the actuators.

In addition, two or more of the actuators facing each other across the center of the through-hole may be opposite in the rotational directions of the rotary shafts of the motors. Therefore, according to the substrate processing apparatus of the embodiment, it is possible to suppress the vibration of the stage due to the driving of the actuators.

Further, in all of the actuators, the rotational directions of the rotary shafts of the motors of the actuators facing each other across the center of the through-hole may be opposite to each other. Therefore, according to the substrate processing apparatus of the embodiment, it is possible to further suppress the vibration of the stage due to the driving of the actuators.

In addition, among the plurality of actuators, two or more actuators adjacent to each other along the circumferential direction of the through-hole may be opposite in the rotational directions of the rotary shafts of the motors. Therefore, according to the substrate processing apparatus of the embodiment, it is possible to suppress the vibration of the stage due to the driving of the actuators.

Further, in all of the actuators, the rotational directions of the rotary shafts of the motors of the actuators adjacent to each other along the circumferential direction of the through-hole may be opposite to each other. Therefore, according to the substrate processing apparatus of the embodiment, it is possible to further suppress the vibration of the stage due to the driving of the actuators.

Further, the motors in the plurality of actuators may be arranged closer to the bottom portion of the processing container than the movable member. Therefore, according to the substrate processing apparatus of the embodiment, it is possible to further suppress the vibration of the stage due to the driving of the actuators.

Further, the temperature control mechanism may be provided on at least one of the bottom portion of the processing container and the fixed member. Therefore, according to the substrate processing apparatus of the embodiment, it is possible to reduce the risk of the motor failure due to the heat of the substrate processing performed in the processing container.

Further, the rotation speed of the rotary shaft of the motor may be controlled according to a cam curve. Therefore, according to the substrate processing apparatus of the embodiment, it is possible to further suppress the vibration of the stage due to the driving of the actuators.

### Other Modifications

The technique disclosed in the subject application is not limited to the above-described embodiment, and various modifications may be made within the scope of the gist thereof.

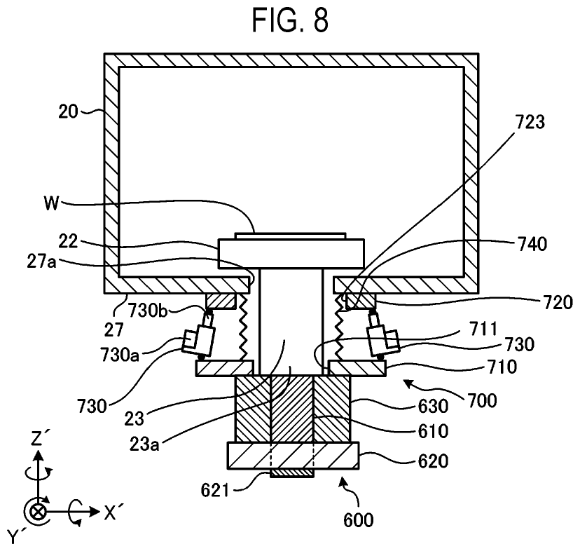

For example, in the above-described embodiment, there has been described the example in which the motors 730a of the plurality of actuators 730 are arranged closer to the bottom portion 27 of the processing container 20 than the movable member 710. However, the arrangement positions of the motors 730a are not limited thereto. FIG. 8 is a diagram showing another example of the arrangement positions of the motors 730a. For example, as shown in FIG. 8, the motors 730a of the plurality of actuators 730 may be arranged closer to the movable member 710 than the bottom portion 27 of the processing container 20. With this configuration, the motors 730a are located away from the bottom portion 27 of the processing container 20. Accordingly, it is possible to reduce the risk of failure of the motors 730a due to the heat of the substrate processing performed in the processing container 20.

In addition, the motors 730a of the plurality of actuators 730 may be alternately arranged along the circumferential direction of the through-hole 27a at the positions closer to the bottom portion 27 of the processing container 20 than the movable member 710 and at the positions closer to the movable member 710 than the bottom portion 27 of the processing container 20. With this configuration, it is possible to reduce the installation space for the motors 730a.

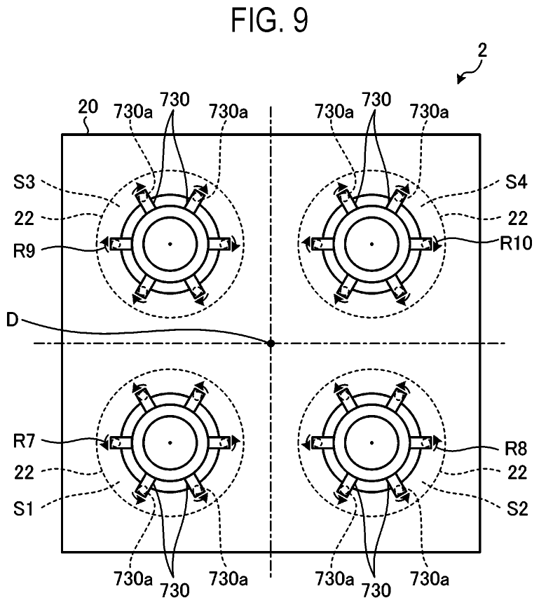

Further, in the above-described embodiment, there has been described the case where, among the plurality of actuators 730 for moving one stage 22, the rotational directions R of the rotary shafts of the motors 730a of two or more actuators 730 having a predetermined positional relationship are opposite to each other. However, the disclosed technique is not limited thereto. For example, as shown in FIG. 9, in the actuators 730 that move two or more stages 22 having a predetermined positional relationship among a plurality of stages 22, the rotational directions R of the rotary shafts of the motors 730a may be opposite to each other. FIG. 9 is an explanatory diagram for explaining another example of the rotational directions R of the rotary shafts of the motors 730a of the plurality of actuators 730. For example, the rotational directions R7 and R10 of the motors 730a of the two stages 22 (the stages 22 in the processing spaces S1 and S4) facing each other across a center D of the processing container 20 among the plurality of (four) stages 22 shown in FIG. 9 are opposite to each other. Further, the rotational directions R8 and R9 of the motors 730a of the two stages 22 (the stages 22 in the processing spaces S2 and S3) facing each other across the center D of the processing container 20 among the plurality of stages 22 are opposite to each other. With such a configuration, the reaction torques of the motors 730a of the two or more actuators 730 having a predetermined positional relationship in the processing container 20 cancel each other. As a result, it is possible to suppress the vibration of the processing container 20 due to the driving of the actuators 730.

It should be noted that the embodiments disclosed herein are exemplary in all respects and not limitative. Indeed, the embodiments described above may be implemented in various forms. Further, the above-described embodiments may be omitted, replaced, or modified in various forms without departing from the scope and spirit of the appended claims.

Regarding the above-described embodiments, the following supplementary notes are further disclosed.

### Supplementary Note 1

A substrate processing apparatus includes: a processing container; a stage provided inside the processing container and configured to place a substrate thereon; a support member configured to penetrate a through-hole of a bottom portion of the processing container and support the stage from below; a movable member located outside the processing container, connected to an end portion of the support member, and configured to move integrally with the stage; a fixed member fixed around the through-hole outside the processing container; and a plurality of actuators provided in parallel with each other between the fixed member and the movable member and configured to move the movable member and the stage, wherein each of the plurality of actuators includes a motor and a rod, and is configured to expand and contract the rod by rotation of a rotary shaft of the motor to move the movable member and the stage, and two or more actuators having a predetermined positional relationship among the plurality of actuators are opposite in rotational directions of the rotary shafts of the motors.

### Supplementary Note 2

In the apparatus of Supplementary Note 1 above, among the plurality of actuators, two or more actuators facing each other across a center of the through-hole are opposite in the rotational directions of the rotary shafts of the motors.

### Supplementary Note 3

In the apparatus of Supplementary Note 1 or 2 above, in all of the plurality of actuators, the rotational directions of the rotary shafts of the motors of the actuators facing each other across the center of the through-hole are opposite to each other.

### Supplementary Note 4

In the apparatus of any one of Supplementary Notes 1 to 3 above, among the plurality of actuators, the two or more actuators adjacent to each other along a circumferential direction of the through-hole are opposite in the rotational directions of the rotary shafts of the motors.

### Supplementary Note 5

In the apparatus of any one of Supplementary Notes 1 to 4 above, in all of the plurality of actuators, the rotational directions of the rotation shafts of the two or more motors of the actuators adjacent to each other along the circumferential direction of the through-hole are opposite to each other.

### Supplementary Note 6

In the apparatus of any one of Supplementary Notes 1 to 5 above, the motors of the plurality of actuators are arranged at positions closer to the bottom portion of the processing container than the movable member.

### Supplementary Note 7

In the apparatus of Supplementary Note 6 above, a temperature control mechanism is provided on at least one of the bottom portion of the processing container or the fixed member.

### Supplementary Note 8

In the apparatus of any one of Supplementary Notes 1 to 5 above, the motors of the plurality of actuators are arranged at positions closer to the movable member than the bottom portion of the processing container.

### Supplementary Note 9

In the apparatus of any one of Supplementary Notes 1 to 5 above, the motors of the plurality of actuators are alternately arranged along the circumferential direction of the through-hole at positions closer to the bottom portion of the processing container than the movable member and at positions closer to the movable member than the bottom portion of the processing container.

### Supplementary Note 10

In the apparatus of any one of Supplementary Notes 1 to 9 above, the rotational speed of the rotary shaft of the motor is controlled according to a cam curve.

### Supplementary Note 11

A substrate processing apparatus includes: a processing container; a stage provided inside the processing container and configured to place a substrate thereon; a support member configured to penetrate a through-hole of a bottom portion of the processing container and support the stage from below; a movable member located outside the processing container, connected to an end portion of the support member, and configured to move integrally with the stage; a fixed member fixed around the through-hole outside the processing container; and a plurality of actuators provided in parallel with each other between the fixed member and the movable member and configured to move the movable member and the stage, wherein each of the plurality of actuators includes a motor and a rod, and is configured to expand and contract the rod by rotation of a rotary shaft of the motor to move the movable member and the stage, and the stage includes a plurality of stages provided inside the processing container, and the rotational directions of the rotary shafts of the motors are opposite from each other in the two or more actuators among the plurality of actuators that move two or more stages having a predetermined positional relationship among the plurality of stages.

According to the present disclosure in some embodiments, it is possible to suppress the vibration of a stage generated when driving a plurality of actuators.

While certain embodiments have been described, these embodiments have been presented by way of example only, and are not intended to limit the scope of the disclosures. Indeed, the embodiments described herein may be embodied in a variety of other forms. Further, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a processing container;
a stage provided inside the processing container and configured to place a substrate thereon;
a support member configured to penetrate a through-hole of a bottom portion of the processing container and support the stage from below;
a movable member located outside the processing container, connected to an end portion of the support member, and configured to move integrally with the stage;
a fixed member fixed around the through-hole outside the processing container; and
a plurality of actuators provided in parallel with each other between the fixed member and the movable member and configured to move the movable member and the stage,
wherein each of the plurality of actuators includes a motor and a rod, and is configured to expand and contract the rod by rotation of a rotary shaft of the motor so as to move the movable member and the stage, and
wherein two or more actuators having a predetermined positional relationship among the plurality of actuators are opposite in rotational directions of the rotary shafts of the motors.

2. The substrate processing apparatus of claim 1, wherein, among the plurality of actuators, the two or more actuators facing each other across a center of the through-hole are opposite in the rotational directions of the rotary shafts of the motors.

3. The substrate processing apparatus of claim 2, wherein, in all of the plurality of actuators, the rotational directions of the rotary shafts of the motors of the actuators facing each other across the center of the through-hole are opposite to each other.

4. The substrate processing apparatus of claim 1, wherein, among the plurality of actuators, the two or more actuators adjacent to each other along a circumferential direction of the through-hole are opposite in the rotational directions of the rotary shafts of the motors.

5. The substrate processing apparatus of claim 4, wherein, in all of the plurality of actuators, the rotational directions of the rotation shafts of the two or more motors of the actuators adjacent to each other along the circumferential direction of the through-hole are opposite to each other.

6. The substrate processing apparatus of claim 1, wherein the motors of the plurality of actuators are arranged at positions closer to the bottom portion of the processing container than the movable member.

7. The substrate processing apparatus of claim 6, wherein a temperature control mechanism is provided on at least one of the bottom portion of the processing container or the fixed member.

8. The substrate processing apparatus of claim 1, wherein the motors of the plurality of actuators are arranged at positions closer to the movable member than the bottom portion of the processing container.

9. The substrate processing apparatus of claim 1, wherein the motors of the plurality of actuators are alternately arranged along a circumferential direction of the through-hole at positions closer to the bottom portion of the processing container than the movable member and at positions closer to the movable member than the bottom portion of the processing container.

10. The substrate processing apparatus of claim 1, wherein a rotational speed of the rotary shaft of the motor is controlled according to a cam curve.

11. A substrate processing apparatus, comprising:
a processing container;
a stage provided inside the processing container and configured to place a substrate thereon;
a support member configured to penetrate a through-hole of a bottom portion of the processing container and support the stage from below;
a movable member located outside the processing container, connected to an end portion of the support member, and configured to move integrally with the stage;
a fixed member fixed around the through-hole outside the processing container; and
a plurality of actuators provided in parallel with each other between the fixed member and the movable member and configured to move the movable member and the stage,
wherein each of the plurality of actuators includes a motor and a rod, and is configured to expand and contract the rod by rotation of a rotary shaft of the motor so as to move the movable member and the stage, and
wherein the stage includes a plurality of stages provided inside the processing container, and rotational directions of the rotary shafts of the motors are opposite from each other in two or more actuators among the plurality of actuators that move two or more stages having a predetermined positional relationship among the plurality of stages.
